(19) United States
(12) Patent Application Publication
(10) Pub. No.: US 2026/0173964 A1
(43) Pub. Date: Jun. 18, 2026

(54) SEMICONDUCTOR DEVICE

(71) Applicant: Samsung Electronics Co., Ltd., Suwon-si (KR)

(72) Inventors: Jubin SEO, Suwon-si (KR); Ho-Jin LEE, Suwon-si (KR)

(73) Assignee: Samsung Electronics Co., Ltd., Suwon-si (KR)

(21) Appl. No.: 19/254,156

(22) Filed: Jun. 30, 2025

(30) Foreign Application Priority Data
Dec. 13, 2024 (KR) 10-2024-0186411

(51) Int. Cl. H01L 23/00; H01L 25/065

(52) U.S. Cl. CPC H10W 90/00; H10W 72/01935; H10W 72/01938; H10W 72/01951; H10W 72/921; H10W 72/923; H10W 72/934; H10W 72/952; H10W 80/312; H10W 80/327; H10W 90/26; H10W 90/297; H10W 90/792

(57) ABSTRACT

A semiconductor device may include a first semiconductor die including a first pad and a first adhesive layer covering an upper portion of a side wall of the first pad, a second semiconductor die including a second pad and a second adhesive layer covering a lower portion of a side wall of the second pad, and a first protection layer between the first pad and the second adhesive layer. A mean grain size of each of the first pad and the second pad may range from 25 nm to 70 nm. The second pad may be on the first pad, a top surface of the first pad may include a portion exposed by the second pad, and the second adhesive layer may be on the exposed portion of the first pad. The protection layer may be between the exposed portion of the first pad and the second adhesive layer.

### CROSS-REFERENCE TO RELATED APPLICATIONS

This U.S. non-provisional patent application claims priority under 35 U.S.C. § 119 to Korean Patent Application No. 10-2024-0186411, filed on Dec. 13, 2024, in the Korean Intellectual Property Office, the entire contents of which are hereby incorporated by reference.

### BACKGROUND

The present disclosure relates to semiconductor devices.

A semiconductor package is configured to facilitate the use of an integrated circuit chip as a component in an electronic product. Conventionally, the semiconductor package includes a printed circuit board (PCB) and a semiconductor chip die, which is mounted on the PCB and is electrically connected to the PCB using bonding wires or bumps. With development of the electronics industry, many studies are being conducted to improve reliability of the semiconductor package and to reduce a size of the semiconductor package.

### SUMMARY

Some example embodiment of the inventive concepts provide semiconductor devices with improved electrical and/or reliability characteristics.

Some example embodiments of the inventive concepts provide methods of fabricating a semiconductor device with improved electrical and/or reliability characteristics.

According to an example embodiment of the inventive concepts, a semiconductor device includes a first semiconductor die including a first pad and a first adhesive layer, the first adhesive layer covering an upper portion of a side wall of the first pad, a second semiconductor die including a second pad and a second adhesive layer, the second adhesive layer covering a lower portion of a side wall of the second pad, and a first protection layer between the first pad and the second adhesive layer, wherein a mean grain size of each of the first pad and the second pad is from 25 nm to 70 nm, the second pad is on the first pad, a top surface of the first pad includes an exposed top surface portion exposed by the second pad, the second adhesive layer is on the exposed top surface portion of the first pad, and the protection layer is between the exposed top surface portion of the first pad and the second adhesive layer.

According to an example embodiment of the inventive concepts, a semiconductor device includes a first semiconductor die, a second semiconductor die on the first semiconductor die, and a first protection layer between the first semiconductor die and the second semiconductor die, wherein the first semiconductor die includes a first substrate, a first interconnection pattern on the first substrate, a first via on the first interconnection pattern, a first insulating layer on the substrate and covering the first interconnection pattern and the first via, a first adhesive layer on the first insulating layer, and a first pad penetrating the first adhesive layer and the first insulating layer and connected to the first via, the second semiconductor die includes a second substrate, a second interconnection pattern on the second substrate, a second via on the second interconnection pattern, a second insulating layer on the substrate and covering the second interconnection pattern and the second via, a second adhesive layer on the second insulating layer, and a second pad penetrating the second adhesive layer and the second insulating layer and connected to the second via, a mean grain size of each of the first pad and the second pad ranges from 25 nm to 70 nm, the second pad is on the first pad, and a top surface the first pad includes an exposed top surface portion exposed by the second pad, the second adhesive layer is on the exposed top surface portion of the first pad, and the first protection layer is between the exposed top surface portion of the first pad and the second adhesive layer.

According to an example embodiment of the inventive concepts, a method of manufacturing a semiconductor device includes forming a first semiconductor die by forming a first substrate including a first circuit layer, forming a first interconnection pattern on a top surface of the first substrate to be electrically connected to the first circuit layer, forming a first insulating layer on the top surface of the first substrate to cover the first interconnection pattern, forming a first adhesive layer on the first insulating layer, forming a first opening to penetrate the first adhesive layer and a portion of the first insulating layer using a first mask pattern, forming a second opening to penetrate a portion of the first insulating layer 110 and to expose the first interconnection pattern using a second mask pattern such that the second opening includes a first portion and a second portion, the first lower portion being a lower portion of the second opening and exposing a top surface of the fist interconnection pattern, the first upper portion being an upper portion of the second opening, forming a first seed pattern and a first protection seed pattern to conformally cover an inner side wall of the second opening to form a third opening, the third opening including a second lower portion and a second upper portion, forming a preliminary first via in the second lower portion of the third opening and a preliminary first pad in the second upper portion of the third opening, forming a second semiconductor die by forming a second substrate including a second circuit layer, forming a second interconnection pattern on a bottom surface of the second substrate to be electrically connected to the second circuit layer, forming a second insulating layer on the bottom surface of the second substrate to cover the second interconnection pattern, forming a second adhesive layer under the second insulating layer, forming a fourth opening to penetrate the second adhesive layer and a portion of the second insulating layer using a third mask pattern, forming a fifth opening to penetrate a portion of the second insulating layer and to expose the second interconnection pattern using a fourth mask pattern such that the fifth opening includes a lower portion and an upper portion, the third lower portion being a lower portion of the second opening and exposing a top surface of the second interconnection pattern, the third upper portion being an upper portion of the second opening, forming a second seed pattern to conformally cover an inner side wall of the fifth opening to form a sixth opening, the sixth opening including a fourth lower portion and a fourth upper portion, and forming a preliminary second via in the fourth lower portion of the sixth opening and a preliminary second pad in the fourth upper portion of the sixth opening attaching the second semiconductor die to the first semiconductor die such that a top surface of the first adhesive layer is in contact with a bottom surface of the second adhesive layer; and performing an annealing process to form a protection layer between a portion of a top surface of the first pad exposed by the second pad and the second adhesive layer.

The forming the preliminary first via and the preliminary first pad may form the preliminary first via and the preliminary first pad to have a mean grain size ranging from 25 nm to 70 nm.

The second opening may have a stepwise structure at a boundary between the first lower portion and first upper portion of the second opening and the first lower portion and first upper portion of the second opening may have different widths from each other in a first direction parallel to a top surface of the first adhesive layer.

### BRIEF DESCRIPTION OF THE DRAWINGS

FIG. 1 is a sectional view illustrating a semiconductor device according to an example embodiment of the inventive concepts.

FIGS. 2A, 2C, and 2E are enlarged sectional views, each of which illustrates a portion ‘A’ of FIG. 1 according to an example embodiment of the inventive concepts.

FIGS. 2B, 2D, and 2F are plan views of the semiconductor devices shown in FIGS. 2A, 2C, and 2E, respectively, as observed when the semiconductor devices are cut at a level of a bottom surface of a second adhesive layer.

FIGS. 3 to 13 are sectional views illustrating a method of fabricating a semiconductor device according to some example embodiments of the inventive concepts.

### DETAILED DESCRIPTION

Example embodiments of the inventive concepts will now be described more fully with reference to the accompanying drawings, in which some example embodiments are shown.

As used herein, expressions such as “one of,” “one or more of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

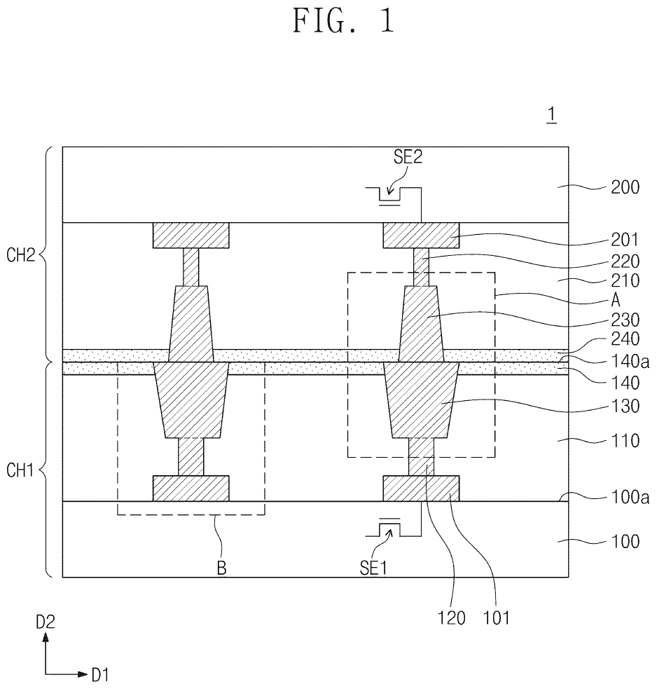

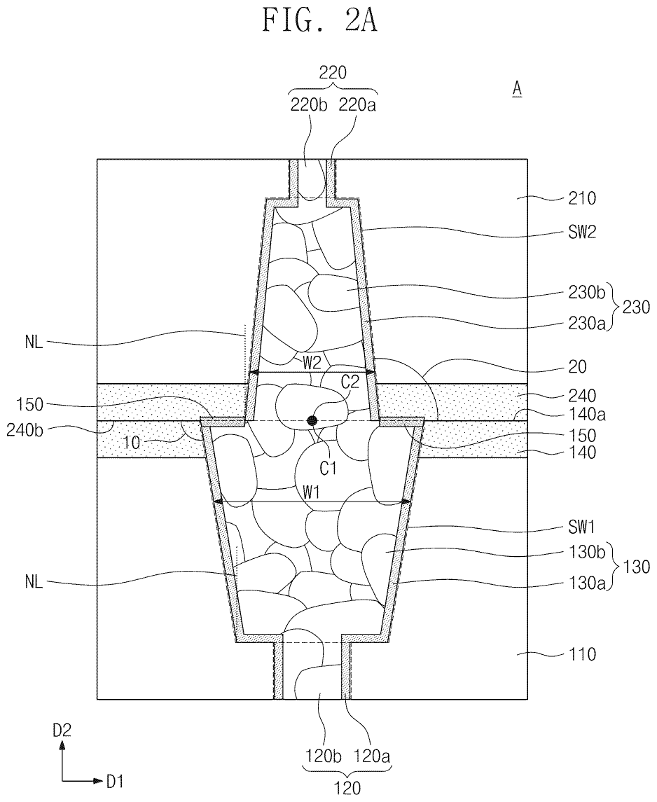

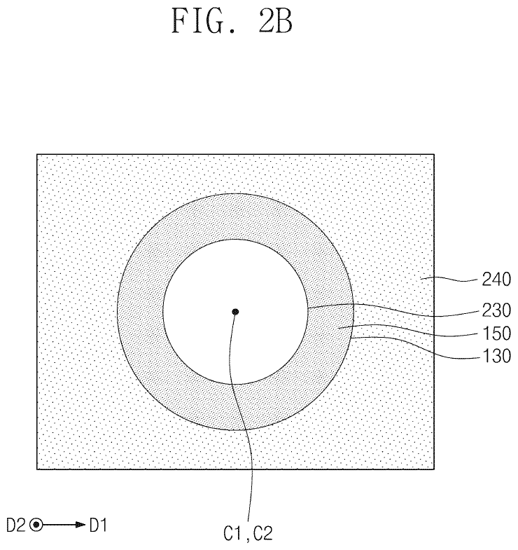

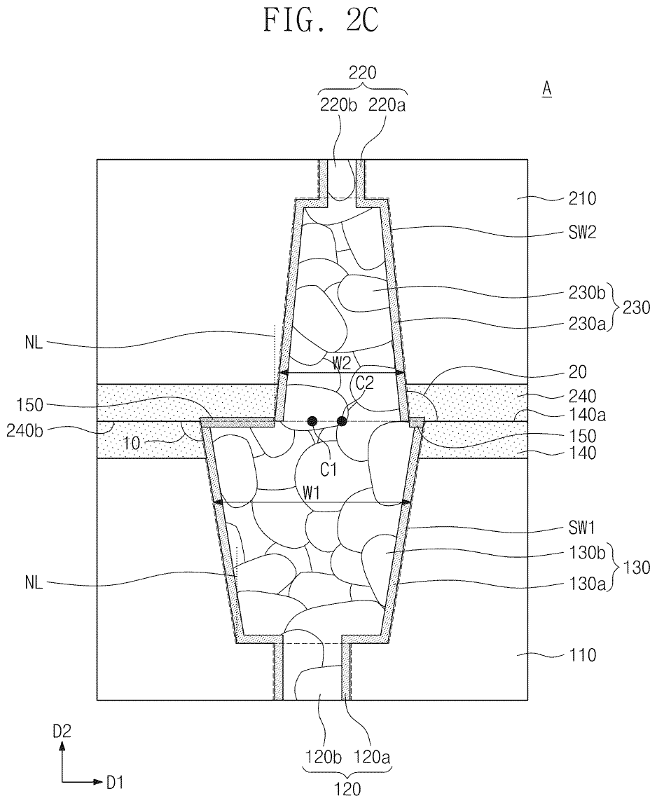

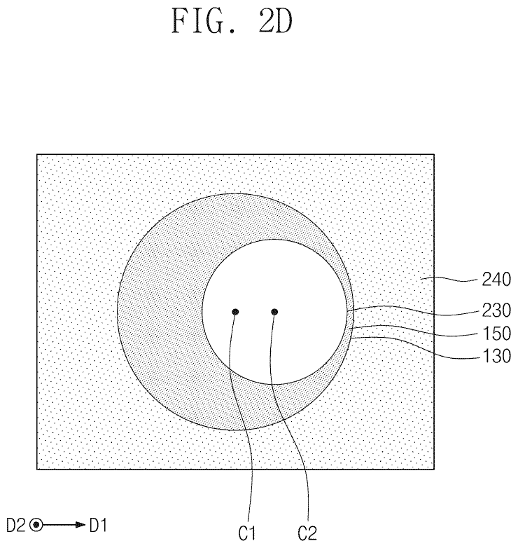

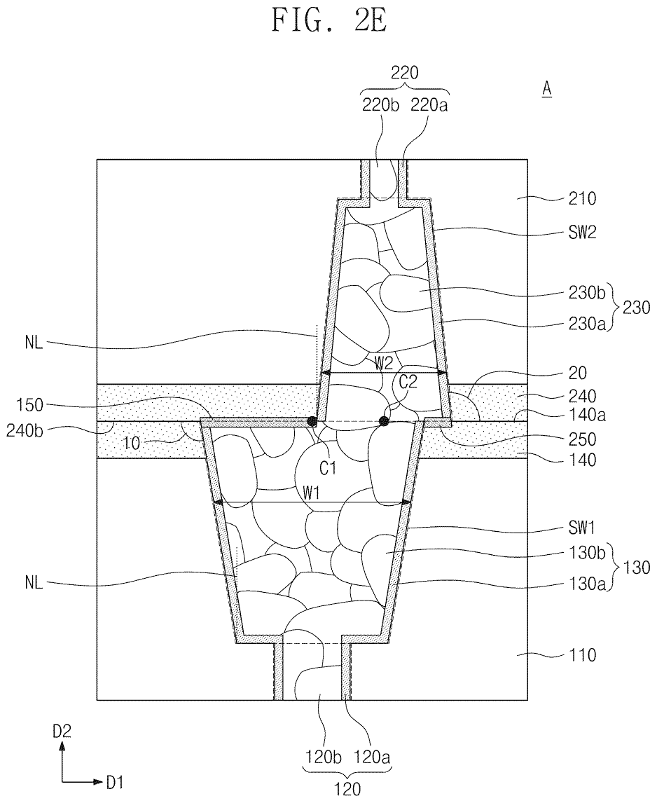

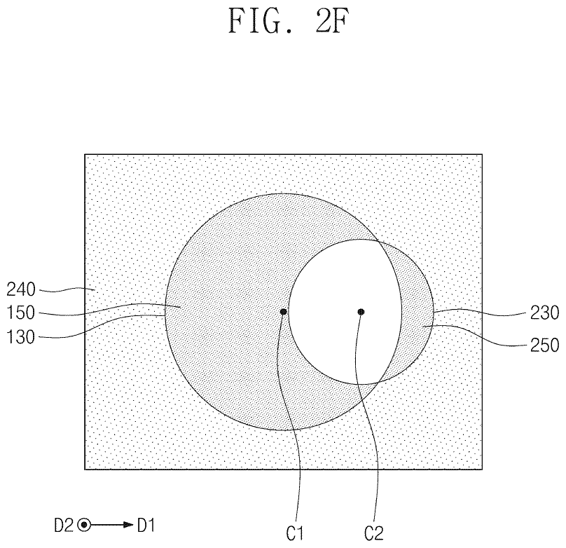

FIG. 1 is a sectional view illustrating a semiconductor device according to an example embodiment of the inventive concepts. FIGS. 2A, 2C, and 2E are enlarged sectional views, each of which illustrates a portion ‘A’ of FIG. 1 according to an example embodiment of the inventive concepts. FIGS. 2B, 2D, and 2F are plan views of the semiconductor devices shown in FIGS. 2A, 2C, and 2E, respectively, as observed when the semiconductor devices are cut at a level of a bottom surface of a second adhesive layer.

Referring to FIG. 1, a semiconductor device 1 may include a first semiconductor die CH1 and a second semiconductor die CH2.

The first semiconductor die CH1 may include a first substrate 100, a first interconnection pattern 101, a first insulating layer 110, a first adhesive layer 140, a first via 120, and a first pad 130.

The first substrate 100 may be extended in a first direction D1 parallel to a top surface 100a of the first substrate 100. In the present specification, the first direction D1 may be parallel to the top surface 100a of the first substrate 100, and a second direction D2 may be a vertical direction D2 that is perpendicular to the top surface 100a of the first substrate 100. For example, the first and second directions D1 and D2 may be orthogonal to each other. Furthermore, the first direction D1 may be parallel to a top surface 140a of the first adhesive layer 140, which will be described below, and the second direction D2 may be perpendicular to the top surface 140a of the first adhesive layer 140.

The first substrate 100 may include a semiconductor substrate including a semiconductor material. The first substrate 100 may be formed of or include at least one of, for example, silicon (Si), germanium (Ge), silicon germanium (SiGe), gallium arsenic (GaAs), indium gallium arsenic (InGaAs), or aluminum gallium arsenic (AlGaAs).

The first substrate 100 may include a first circuit layer SE1. Although not shown, the first circuit layer SE1 may include transistors and may further include a plurality of circuit interconnection lines and a plurality of contact plugs, which are connected to the transistors. As another example, the first circuit layer SE1 may include a logic circuit or a memory circuit. The first circuit layer SE1 may be connected to the first interconnection pattern 101 to be described below. Although not shown, the first substrate 100 may further include a plurality of circuit interconnection lines connecting the first circuit layer SE1 to the first interconnection pattern 101.

The first interconnection pattern 101 may be provided on the top surface 100a of the first substrate 100. In an example embodiment, a plurality of first interconnection patterns 101 may be provided. Each of the first interconnection patterns 101 may be electrically connected to the corresponding first circuit layer SE1 of the first substrate 100. Although not shown, an additional insulating layer and additional circuit interconnection lines may be provided between the first interconnection patterns 101 and the first substrate 100. The first interconnection patterns 101 may include at least one of a metallic material or a conductive material (e.g., copper).

The first insulating layer 110 may be provided on the first substrate 100. The first insulating layer 110 may cover the first interconnection patterns 101. In an example embodiment, the first insulating layer 110 may include a plurality of insulating layers, unlike the illustrated example. The first insulating layer 110 may be formed of or include at least one of insulating materials (e.g., silicon oxide, silicon nitride, silicon oxynitride, and/or low-k dielectric materials).

The first via 120 may be provided on the first interconnection pattern 101. The first via 120 may be provided in the first insulating layer 110. In an example embodiment, a plurality of first vias 120 may be provided. Each of the first vias 120 may be connected to a corresponding one of the first interconnection patterns 101. Each of the first vias 120 may be electrically connected to the corresponding first circuit layer SE1, which is provided in the first substrate 100, through a corresponding one of the first interconnection patterns 101.

The first adhesive layer 140 may be disposed on the first insulating layer 110. In an example embodiment, the first adhesive layer 140 may be formed of or include silicon oxide or silicon carbon nitride.

The first pad 130 may be provided on the first via 120. The first pad 130 may penetrate the first adhesive layer 140 and a portion of the first insulating layer 110. In an example embodiment, a plurality of first pads 130 may be provided. Each of the first pads 130 may be connected to a corresponding one of the first vias 120. Each of the first pads 130 may be electrically connected to a corresponding one of the first circuit layers SE1 through a corresponding one of the first vias 120.

The second semiconductor die CH2 may include a second substrate 200, a second interconnection pattern 201, a second insulating layer 210, a second adhesive layer 240, a second via 220, and a second pad 230.

The second substrate 200 may be extended in the first direction D1. The second substrate 200 may include a semiconductor substrate including a semiconductor material. The second substrate 200 may be formed of or include at least one of, for example, silicon (Si), germanium (Ge), silicon germanium (SiGe), gallium arsenic (GaAs), indium gallium arsenic (InGaAs), or aluminum gallium arsenic (AlGaAs).

The second substrate 200 may include a second circuit layer SE2. Although not shown, the second circuit layer SE2 may include transistors and may further include a plurality of circuit interconnection lines and a plurality of contact plugs, which are connected to the transistors. As another example, the second circuit layer SE2 may include a logic circuit or a memory circuit. The second circuit layer SE2 may be connected to the second interconnection pattern 201 to be described below. Although not shown, the second substrate 200 may further include a plurality of circuit interconnection lines connecting the second circuit layer SE2 to the second interconnection pattern 201.

The second interconnection pattern 201 may be provided on a bottom surface of the second substrate 200. In an example embodiment, a plurality of second interconnection patterns 201 may be provided. Each of the second interconnection patterns 201 may be electrically connected to the corresponding second circuit layer SE2 of the second substrate 200. Although not shown, an additional insulating layer and additional circuit interconnection lines may be provided between the second interconnection patterns 201 and the second substrate 200. The second interconnection patterns 201 may include at least one of a metallic material or a conductive material (e.g., copper).

The second insulating layer 210 may be provided on a bottom surface of the second substrate 200. The second insulating layer 210 may cover the second interconnection patterns 201. In an example embodiment, the second insulating layer 210 may include a plurality of insulating layers, unlike the illustrated example. The second insulating layer 210 may be formed of or include at least one of insulating materials (e.g., silicon oxide, silicon nitride, silicon oxynitride, and/or low-k dielectric materials).

The second via 220 may be provided on the second interconnection pattern 201. The second via 220 may be provided in the second insulating layer 210. In an example embodiment, a plurality of second vias 220 may be provided. Each of the second vias 220 may be connected to a corresponding one of the second interconnection patterns 201. Each of the second vias 220 may be electrically connected to the corresponding second circuit layer SE2, which is provided in the second substrate 200, through a corresponding one of the second interconnection patterns 201.

The second adhesive layer 240 may be disposed on the second insulating layer 210. The second adhesive layer 240 may be formed of or include silicon oxide or silicon carbon nitride.

The second pad 230 may be provided on the second via 220. The second pad 230 may penetrate the second adhesive layer 240 and a portion of the second insulating layer 210. In an example embodiment, a plurality of second pads 230 may be provided. Each of the second pads 230 may be connected to a corresponding one of the second vias 220. Each of the second pads 230 may be electrically connected to the corresponding second circuit layer SE2 through a corresponding one of the second vias 220.

Referring to FIG. 2A, the first adhesive layer 140 of the first semiconductor die CH1 may be in contact with the second adhesive layer 240 of the second semiconductor die CH2. In detail, the top surface 140a of the first adhesive layer 140 may be in contact with a bottom surface 240b of the second adhesive layer 240. In addition, the first pad 130 may be in contact with the second pad 230. Some example embodiments of the inventive concepts will be described in more detail with reference to FIGS. 2A to 2F.

Referring to FIGS. 2A and 2B, the semiconductor device 1 may have a hybrid bonding structure. The uppermost portion of the first pad 130 may be in contact with the lowermost portion of the second pad 230, and the top surface 140a of the first adhesive layer 140 may be in contact with the bottom surface 240b of the second adhesive layer 240.

The first via 120 may include a first via seed pattern 120a and a first via conductive pattern 120b. The first via conductive pattern 120b may be disposed on the first via seed pattern 120a.

The first pad 130 may include a first pad seed pattern 130a and a first pad conductive pattern 130b. The first pad conductive pattern 130b may be disposed on the first pad seed pattern 130a.

The first via 120 and the first pad 130 may have a mean grain size ranging from 25 nm to 70 nm.

The second via 220 may include a second via seed pattern 220a and a second via conductive pattern 220b. The second via conductive pattern 220b may be disposed on the second via seed pattern 220a.

The second pad 230 may include a second pad seed pattern 230a and a second pad conductive pattern 230b. The second pad conductive pattern 230b may be disposed on the second pad seed pattern 230a.

The second via 220 and the second pad 230 may have a mean grain size ranging from 25 nm to 70 nm.

The first via seed pattern 120a, the first via conductive pattern 120b, the first pad seed pattern 130a, the first pad conductive pattern 130b, the second via seed pattern 220a, the second via conductive pattern 220b, the second pad seed pattern 230a, and the second pad conductive pattern 230b may include the same or substantially similar material. In an example embodiment, the first via seed pattern 120a, the first via conductive pattern 120b, the first pad seed pattern 130a, the first pad conductive pattern 130b, the second via seed pattern 220a, the second via conductive pattern 220b, the second pad seed pattern 230a, and the second pad conductive pattern 230b may be formed of or include a metallic material (e.g., copper (Cu)).

The first pad 130 may have a first width W1 in the first direction D1. The first width W1 may increase as a distance from the top surface 100a of the substrate 100 in the second direction D2 increases. In other words, the first width W1 may decrease as a distance from the top surface 140a of the first adhesive layer 140 increases (e.g., in an opposite direction of the second direction D2). The first width W1 may be continuously changed as a distance from the top surface 100a of the substrate 100 in the second direction D2 increases. The first width W1 may have the largest value at the topmost portion of the first pad 130 (e.g., at the highest level).

The second pad 230 may have a second width W2 in the first direction D1. The second width W2 may decrease as a distance from the top surface 100a of the substrate 100 in the second direction D2 increases. In other words, the second width W2 may decrease as a distance from the top surface 140a of the first adhesive layer 140 increases (e.g., in the second direction D2). The second width W2 may be continuously changed as a distance from the top surface 100a of the substrate 100 in the second direction D2 increases. The second width W2 may have the largest value at the lowermost portion of the second pad 230 (e.g., at the lowermost level).

The first width W1 of the first pad 130 may be different from the second width W2 of the second pad 230. In an example embodiment, the first width W1 may be larger than the second width W2. In an example embodiment, the first width W1 at the uppermost portion of the first pad 130 may be larger than the second width W2 at the lowermost portion of the second pad 230.

In an example embodiment, the largest value of the first width W1 of the first pad 130 may range from 400 nm to 600 nm. The largest value of the second width W2 of the second pad 230 may be 0.6 to 0.8 times the largest value of the first width W1. In an example embodiment, the largest value of the second width W2 may range from 240 nm to 320 nm, from 360 nm to 480 nm, or from 240 nm to 480 nm.

A side wall SW1 of the first pad 130 and a side wall SW2 of the second pad 230 may be spaced apart from each other in the first direction D1. The side wall SW1 of the first pad 130 and the side wall SW2 of the second pad 230 may have profiles that are opposite to each other. For example, the side wall SW1 of the first pad 130 may have a shape, which is outwardly inclined in the first direction D1 relative to a normal line NL that is perpendicular to the top surface 100a of the substrate 100. The side wall SW2 of the second pad 230 may have a shape, which is inwardly inclined in the first direction D1 relative to the normal line NL.

The side wall SW1 of the first pad 130 may be inclined at a first angle 10 to the top surface 140a of the first adhesive layer 140. The side wall SW2 of the second pad 230 may be inclined at a second angle 20 to the top surface 140a of the first adhesive layer 140. In an example embodiment, the first angle 10 and the second angle 20 may be obtuse angles.

The first semiconductor die CH1 and the second semiconductor die CH2 may be bonded to each other through the first pad 130, the second pad 230, the first adhesive layer 140, and the second adhesive layer 240. For example, the second pad 230 may be disposed on the first pad 130. In addition, the second adhesive layer 240 may be disposed on the first adhesive layer 140. The first pad 130 may be in contact with the second pad 230. The first adhesive layer 140 may be in contact with the second adhesive layer 240. When viewed in a plan view, a center C1 of the first pad 130 and a center of the second pad 230 may overlap each other vertically (e.g., in the second direction D2). The entirety of the second pad 230 may vertically overlap the first pad 130.

The first pad 130 may have a top surface, which is not covered with the second pad 230 and is exposed. The second adhesive layer 240 may be disposed on the exposed top surface of the first pad 130, which is not covered with the second pad 230. A first protection layer 150 may be interposed between the exposed top surface of the first pad 130, which is not covered with the second pad 230, and the second adhesive layer 240. The first protection layer 150 may be symmetrically disposed in the first direction D1, when viewed in a plan view. The first protection layer 150 may be placed at a height that is similar to or the same as a boundary between the first adhesive layer 140 and the second adhesive layer 240. The first protection layer 150 may be placed at a height that is similar to or the same as a boundary between the first pad 130 and the second pad 230. The first pad 130 may be spaced apart from the second adhesive layer 240 with the first protection layer 150 interposed therebetween.

The first protection layer 150 may include manganese (Mn). In an example embodiment, the first protection layer 150 may include manganese oxide. The manganese oxide may include, for example, MnO, Mn₃O₄, Mn₂O₃, MnO₂, MnO₃, or Mn₂O₇.

FIGS. 2C and 2D are diagrams illustrating an example embodiment that is different from the previous example embodiment of FIGS. 2A and 2B. For concise description, a previously-described element may be identified by the same reference number without repeating an overlapping description thereof.

Referring to FIGS. 2C and 2D, the first semiconductor die CH1 and the second semiconductor die CH2 may be bonded to each other. For example, the second pad 230 may be disposed on the first pad 130. In addition, the second adhesive layer 240 may be disposed on the first adhesive layer 140. The first pad 130 may be in contact with the second pad 230. The first adhesive layer 140 may be in contact with the second adhesive layer 240. When viewed in a plan view, the center C1 of the first pad 130 and a center C2 of the second pad 230 may be spaced apart from each other in the first direction D1. That is, the center C1 of the first pad 130 may not be vertically aligned to the center C2 of the second pad 230. The entirety of the second pad 230 may vertically overlap the first pad 130.

The first pad 130 may have a top surface, which is not covered with the second pad 230 and is exposed. The second adhesive layer 240 may be disposed on the exposed top surface of the first pad 130, which is not covered with the second pad 230. A first protection layer 150 may be interposed between the exposed top surface of the first pad 130, which is not covered with the second pad 230, and the second adhesive layer 240. The first protection layer 150 may be asymmetrically disposed in the first direction D1, when viewed in a plan view.

FIGS. 2E and 2F are diagrams illustrating an example embodiment that is different from the previous example embodiment of FIGS. 2A to 2D. For concise description, a previously-described element may be identified by the same reference number without repeating an overlapping description thereof.

Referring to FIGS. 2E and 2F, the first semiconductor die CH1 and the second semiconductor die CH2 may be bonded to each other. For example, the second pad 230 may be disposed on the first pad 130. In addition, the second adhesive layer 240 may be disposed on the first adhesive layer 140. The first pad 130 may be in partial contact with the second pad 230. The first adhesive layer 140 may be in contact with the second adhesive layer 240. When viewed in a plan view, the center C1 of the first pad 130 and the center of the second pad 230 may be spaced apart from each other in the first direction D1. The center of the first pad 130 and the center of the second pad 230 may not be vertically aligned to each other. A portion of the first pad 130 and a portion of the second pad 230 may vertically overlap each other.

The first pad 130 may have a top surface, which is not covered with the second pad 230 and is exposed. The second adhesive layer 240 may be disposed on the exposed top surface of the first pad 130, which is not covered with the second pad 230. The first protection layer 150 may be interposed between the exposed top surface of the first pad 130, which is not covered with the second pad 230, and the second adhesive layer 240.

The second pad 230 may have a bottom surface exposed by the first pad 130. The first adhesive layer 140 may be disposed on the exposed bottom surface of the second pad 230, which is exposed by the first pad 130. A second protection layer 250 may be interposed between the exposed bottom surface of the second pad 230, which is exposed by the first pad 130, and the first adhesive layer 140. The second pad 230 may be spaced apart from the first adhesive layer 140 with the second protection layer 250 interposed therebetween.

The second protection layer 250 may include manganese (Mn). In an example embodiment, the second protection layer 250 may contain manganese oxide. The manganese oxide may include, for example, MnO, Mn₃O₄, Mn₂O₃, MnO₂, MnO₃, or Mn₂O₇. In an example embodiment, the second protection layer 250 may include the same or substantially similar material as the first protection layer 150.

According to an example embodiment of the inventive concepts, in the bonding structure between the first and second semiconductor dies CH1 and CH2, the first protection layer 150, which contains the manganese oxide, may be interposed between the first pad 130 and the second adhesive layer 240. In addition, the second protection layer 250, which contains the manganese oxide, may be interposed between the second pad 230 and the first adhesive layer 140. Because the protection layer 150 or 250 containing the manganese oxide is disposed at an interface between the conductive pad 130 or 230 and the adhesive layer 140 or 240, an adhesion strength between the conductive pad 130 or 230 and the adhesive layer 140 or 240 may be increased. In addition, all of the first via 120, the first pad 130, the second via 220, and the second pad 230 may have a mean grain size ranging from 25 nm to 70 nm. In the case where the mean grain size is within the afore-described range, it may be possible to block or prevent the manganese (Mn), which is included in the protection layer 150 or 250, from being diffused into a bonding interface between the first and second pads 130 and 230. Accordingly, the protection layer 150 or 250, which contains the manganese oxide, may be locally provided as an interfacial element between the conductive pad 130 or 230 and the adhesive layer 140 or 240. That is, the manganese may not be diffused into a region between the conductive pads 130 and 230 that are bonded to each other. Thus, the semiconductor device with improved electrical and/or reliability characteristics may be provided.

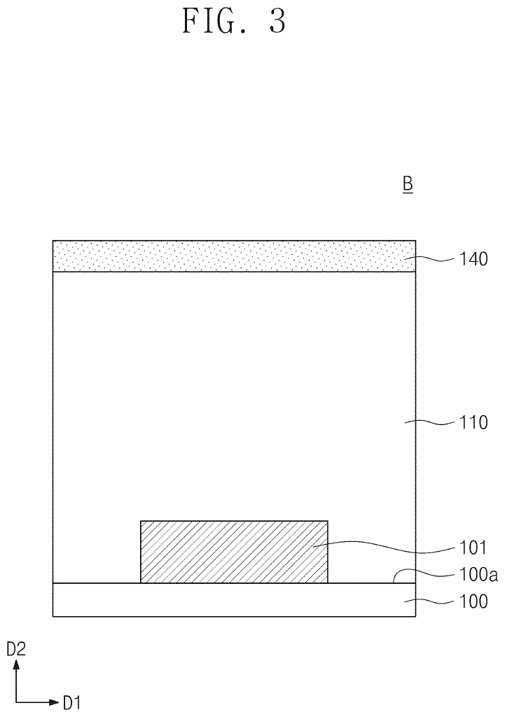

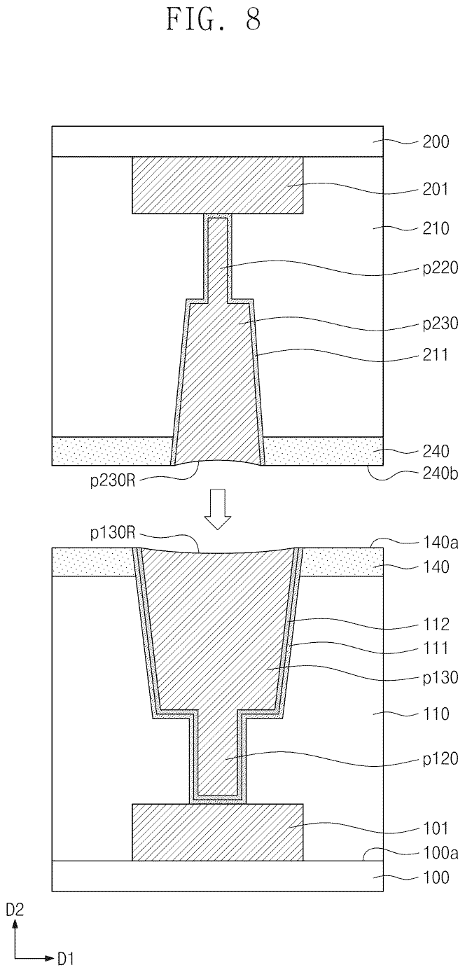

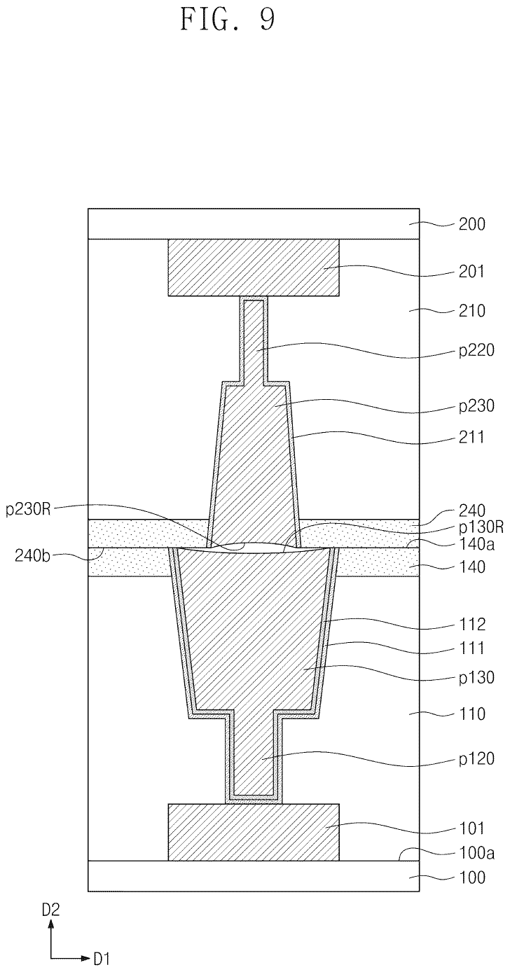

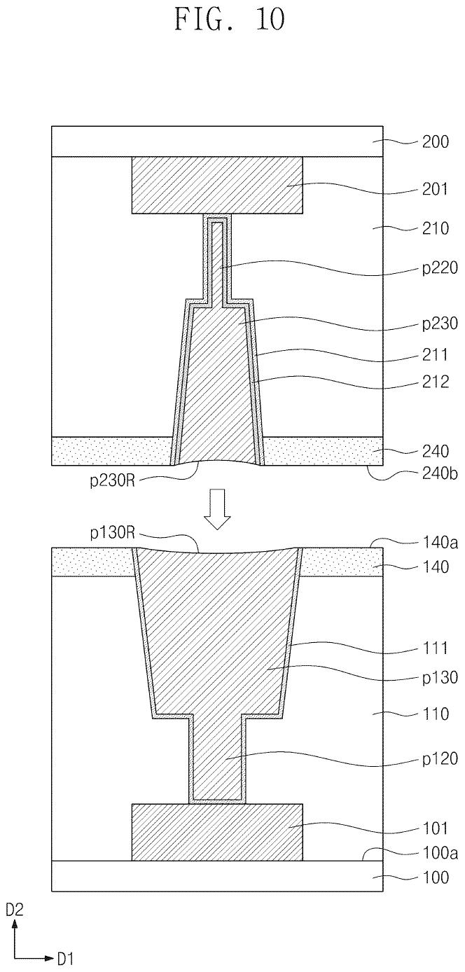

FIGS. 3 to 13 are sectional views illustrating a method of fabricating a semiconductor device according to some example embodiments of the inventive concepts. In detail, FIGS. 3 to 7 are enlarged sectional views illustrating a portion ‘B’ of FIG. 1. FIGS. 8 and 9 are diagrams illustrating a hybrid bonding process according to an example embodiment of the inventive concepts. FIGS. 10 to 13 are diagrams illustrating a hybrid bonding process according to another example embodiment of the inventive concepts. Hereinafter, a method of fabricating a semiconductor device according to some example embodiments of the inventive concepts will be described in more detail with reference to FIG. 1 and FIGS. 3 to 13. However, an overlapping description will be omitted.

Referring to FIGS. 1 and 3, the first substrate 100 including the first circuit layer SE1 may be provided. The first interconnection pattern 101, which is electrically connected to the first circuit layer SE1, may be formed on the top surface 100a of the first substrate 100. In an example embodiment, the formation of the first interconnection pattern 101 may include forming a first interconnection layer (not shown) and patterning the first interconnection layer.

The first insulating layer 110 may be formed on the first substrate 100 to cover the first interconnection pattern 101. The first insulating layer 110 may include a single insulating layer or may include a plurality of insulating layers, unlike the illustrated structure. The first adhesive layer 140 may be formed on the first insulating layer 110. The first insulating layer 110 and the first adhesive layer 140 may be formed using a layer-forming method (e.g., a chemical vapor deposition (CVD) method or a physical vapor deposition (PVD) method).

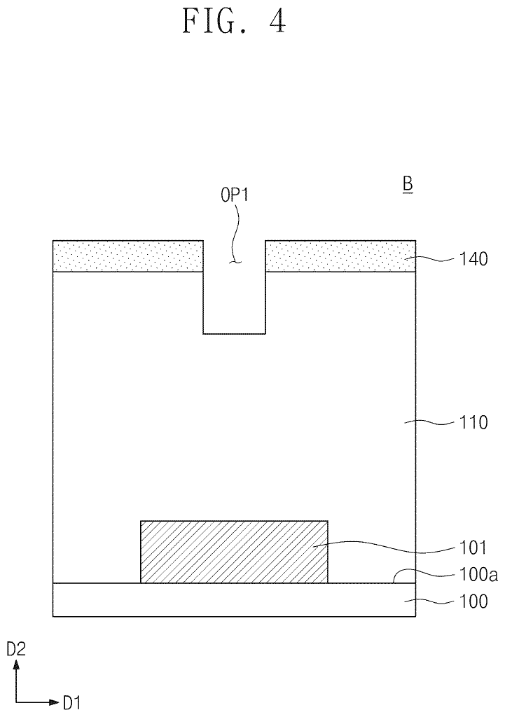

Referring to FIG. 4, a first opening OP1 may be formed to penetrate the first adhesive layer 140 and a portion of the first insulating layer 110. The first opening OP1 may be provided to partially penetrate an upper portion of the first insulating layer 110. In an example embodiment, the formation of the first opening OP1 may include forming a first mask pattern (not shown) on the first adhesive layer 140, performing a first etching process using the first mask pattern as an etch mask, and removing the first mask pattern. The first opening OP1 may be formed to vertically overlap the first interconnection pattern 101.

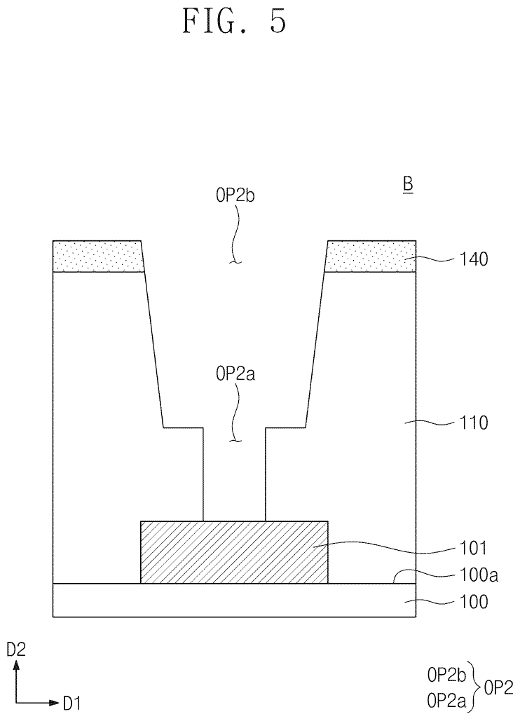

Referring to FIG. 5, a second opening OP2 may be formed to penetrate a portion of the first insulating layer 110 and to expose the first interconnection pattern 101. In an example embodiment, the formation of the second opening OP2 may include forming a second mask pattern (not shown) on the first adhesive layer 140, performing a second etching process using the second mask pattern as an etch mask, and removing the second mask pattern. In an example embodiment, the second etching process may include an anisotropic etching process.

The second opening OP2 may include a first portion OP2a and a second portion OP2b. The first portion OP2a of the second opening OP2 may be a portion, in which the first via 120 described with reference to FIGS. 2A to 2C is formed. The first portion OP2a may be formed to expose a portion of a top surface of the first interconnection pattern 101. The second portion OP2b of the second opening OP2 may be a portion, in which the first pad 130 described with reference to FIGS. 2A to 2C is formed.

The second opening OP2 may have a stepwise structure at a boundary between the first and second portions OP2a and OP2b. The first and second portions OP2a and OP2b may have different widths from each other in the first direction D1. A side wall of the first portion OP2a and a side wall of the second portion OP2b may be spaced apart from each other in the first direction D1. A width of the second opening OP2 in the first direction D1 may be abruptly or discontinuously changed at the boundary between the first and second portions OP2a and OP2b. The width of the second opening OP2 may be abruptly changed at the boundary between the first and second portions OP2a and OP2b.

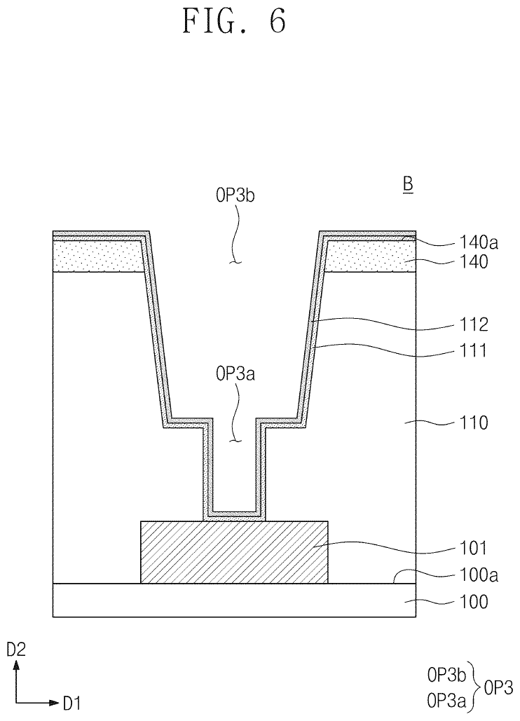

Referring to FIG. 6, a first seed pattern 111 and a first protection seed pattern 112 may be formed to conformally cover an inner side wall of the second opening OP2. The first seed pattern 111 and the first protection seed pattern 112 may be extended to a region on the top surface 140a of the first adhesive layer 140. The first seed pattern 111 and the first protection seed pattern 112 may be formed using a layer-forming method (e.g., chemical vapor deposition (CVD), physical vapor deposition (PVD), and atomic layer deposition (ALD) methods) with a relatively good step coverage property.

A third opening OP3 may be formed by forming the first seed pattern 111 and the first protection seed pattern 112 in the second opening OP2. The third opening OP3 may include a first portion OP3a and a second portion OP3b. The first portion OP3a of the third opening OP3 may refer to the remaining portion of the first portion OP2a of the second opening OP2 in which the first seed pattern 111 and the first protection seed pattern 112 are formed and remain. The second portion OP3b of the third opening OP3 may refer to the remaining portion of the second portion OP2b of the second opening OP2 in which the first seed pattern 111 and the first protection seed pattern 112 are formed and remain.

The first seed pattern 111 may include conductive metal. The first seed pattern 111 may include, for example, copper (Cu).

The first protection seed pattern 112 may include a copper compound. The first protection seed pattern 112 may include, for example, a copper-manganese (CuMn) alloy. In an example embodiment, the first protection seed pattern 112 may include a copper-manganese (CuMn) alloy, in which the mass percentage of manganese (Mn) is less than 1 wt %. In an example embodiment, the first protection seed pattern 112 may include a copper-manganese (CuMn) alloy, in which the mass percentage of manganese (Mn) ranges from 0.4 wt % to 0.6 wt %.

The formation of the first seed pattern 111 and the first protection seed pattern 112 may include depositing a seed material and a growth inhibiting agent. The seed material may include a metallic material. The metallic material may include, for example, copper. The growth inhibiting agent may include an organic material and may include, for example, a hydroxyl group, an amine group, a thiol group, and/or a sulfite group.

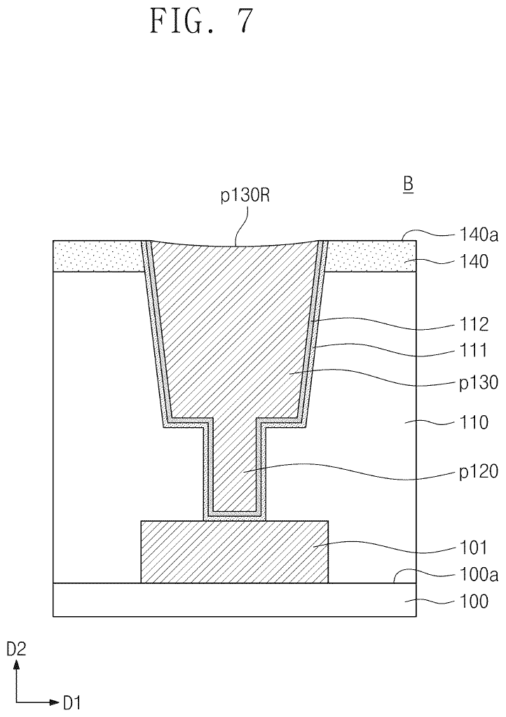

Referring to FIG. 7, a preliminary first via p120 and a preliminary first pad p130 may be formed in the third opening OP3. For example, the preliminary first via p120 may be formed in the first portion OP3a of the third opening OP3, and the preliminary first pad p130 may be formed in the second portion OP3b of the third opening OP3. In an example embodiment, the formation of the preliminary first via p120 and the preliminary first pad p130 may include an electroplating process using the first seed pattern 111 and the first protection seed pattern 112 as an electrode.

A first conductive layer (not shown) may be formed through an electroplating process. Next, a planarization process may be performed on the first conductive layer. The planarization process may be performed using an etch-back process or a chemical mechanical polishing (CMP) process. The planarization process may be performed to expose the top surface 140a of the first adhesive layer 140. After the planarization process, the preliminary first pad p130 may have a recessed top surface p130R that is recessed toward the first substrate 100. The recessed top surface p130R of the preliminary first pad p130 may be placed at a level lower than the top surface 140a of the first adhesive layer 140.

A mean grain size of the preliminary first via p120 and the preliminary first pad p130 may be adjusted by the growth inhibiting agent. In this case, it may be possible to reduce the mean grain size of the preliminary first via p120 and the preliminary first pad p130. In an example embodiment, the preliminary first via p120 and the preliminary first pad p130 may be formed to have the mean grain size ranging from 25 nm to 70 nm.

Referring to FIG. 8, the second substrate 200, the second interconnection pattern 201, the second insulating layer 210, the second adhesive layer 240, a second seed pattern 211, a preliminary second via p220, and a preliminary second pad p230 may be formed. The second substrate 200, the second interconnection pattern 201, the second insulating layer 210, the second adhesive layer 240, the second seed pattern 211, the preliminary second via p220, and the preliminary second pad p230 may be formed through the same or substantially similar method as described with reference to FIGS. 3 to 7. In addition, the second substrate 200, the second interconnection pattern 201, the second insulating layer 210, the second adhesive layer 240, the second seed pattern 211, the preliminary second via p220, and the preliminary second pad p230 may include the same or substantially similar materials as the first substrate 100, the first interconnection pattern 101, the first insulating layer 110, the first adhesive layer 140, the first seed pattern 111, the preliminary first via p120, and the preliminary first pad p130, respectively. In addition, the preliminary second pad p230 may have a recessed bottom surface p230R which is recessed toward the second substrate 200. The recessed bottom surface p230R of the preliminary second pad p230 may be placed at a level higher than the bottom surface 240b of the second adhesive layer 240.

Referring to FIG. 9, the top surface 140a of the first adhesive layer 140 and the bottom surface 240b of the second adhesive layer 240 may be attached to each other. Accordingly, the top surface 140a of the first adhesive layer 140 may be in contact with the bottom surface 240b of the second adhesive layer 240.

A void may be formed between the recessed top surface p130R of the preliminary first pad p130 and the recessed bottom surface p230R of the preliminary second pad p230.

Referring back to FIG. 2A, an annealing process may be performed on the resulting structure of FIG. 9. During the annealing process, a material included in the preliminary first and second pads p130 and p230 may be diffused to fill a void between the recessed top surface p130R of the preliminary first pad p130 and the recessed bottom surface p230R of the preliminary second pad p230. Thus, the first pad 130 may be in contact with the second pad 230, as shown in FIG. 2A.

In addition, a material included in the first protection seed pattern 112 may be diffused to form the first protection layer 150. In an example embodiment, manganese (Mn), which is included in the first protection seed pattern 112, may be diffused into a region between the first pad 130 and the second adhesive layer 240 and may react with oxygen, which is present in the region, to form the first protection layer 150. According to an example embodiment of the inventive concepts, because the first and second pads 130 and 230 have a mean grain size ranging from 25 nm to 70 nm, the manganese (Mn) in the first protection seed pattern 112 may not be diffused into a region between the first and second pads 130 and 230. Thus, the first pad 130 may be spaced apart from the second adhesive layer 240 with the first protection layer 150 interposed therebetween.

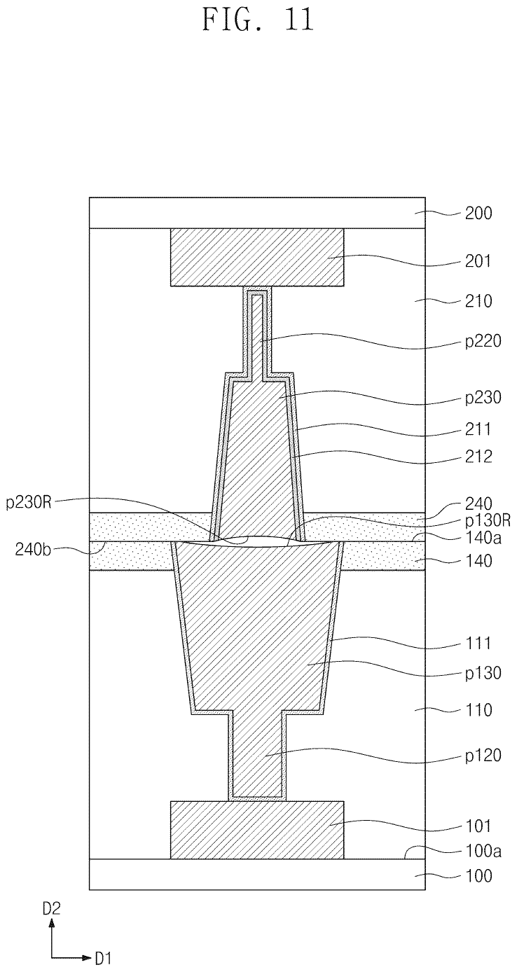

FIGS. 10 and 11 are sectional views illustrating a hybrid bonding process according to an example embodiment of the inventive concepts, which differs from that the example embodiment shown in FIGS. 8 and 9. In the following description, an element previously described with reference to FIGS. 8 and 9 may be identified by the same reference number without repeating an overlapping description thereof.

Referring to FIG. 10, the first protection seed pattern 112 may be omitted, compared to the example embodiment of FIG. 8. However, a second protection seed pattern 212 may be formed. The second protection seed pattern 212 may be formed to conformally cover the second seed pattern 211. The second protection seed pattern 212 may include the same or substantially similar material as the first protection seed pattern 112 described with reference to FIG. 7 and may be formed through the same or substantially similar method as that for the first protection seed pattern 112.

Referring to FIG. 11, the top surface 140a of the first adhesive layer 140 and the bottom surface 240b of the second adhesive layer 240 may be attached to each other. Thus, the top surface 140a of the first adhesive layer 140 may be in contact with the bottom surface 240b of the second adhesive layer 240.

A void may be formed between the recessed top surface p130R of the preliminary first pad p130 and the recessed bottom surface p230R of the preliminary second pad p230.

Referring back to FIG. 2A, an annealing process may be performed on the resulting structure of FIG. 11. During the annealing process, a material included in the preliminary first and second pads p130 and p230 may be diffused to fill a void between the recessed top surface p130R of the preliminary first pad p130 and the recessed bottom surface p230R of the preliminary second pad p230. Thus, the first pad 130 may be in contact with the second pad 230, as shown in FIG. 2A.

In addition, a material included in the second protection seed pattern 212 may be diffused to form the first protection layer 150. In an example embodiment, manganese (Mn) included in the second protection seed pattern 212 may be diffused into a region between the first pad 130 and the second adhesive layer 240 and may react with oxygen, which is present in the region, to form the first protection layer 150.

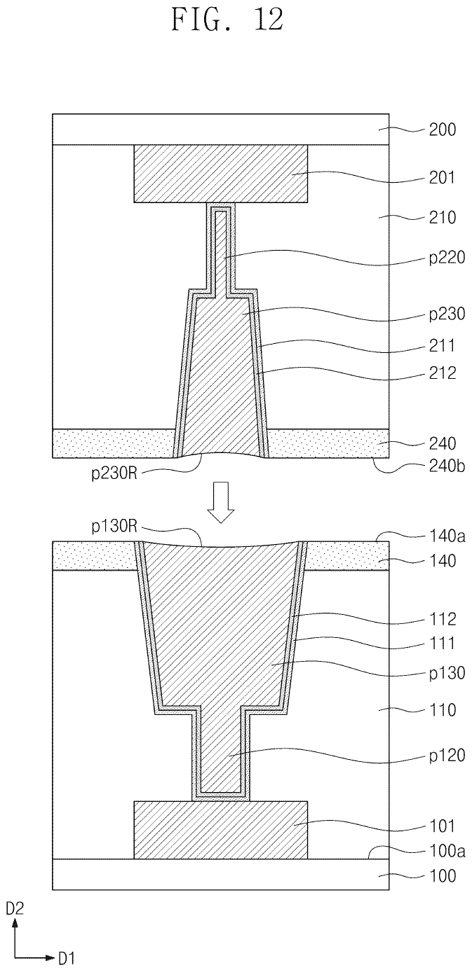

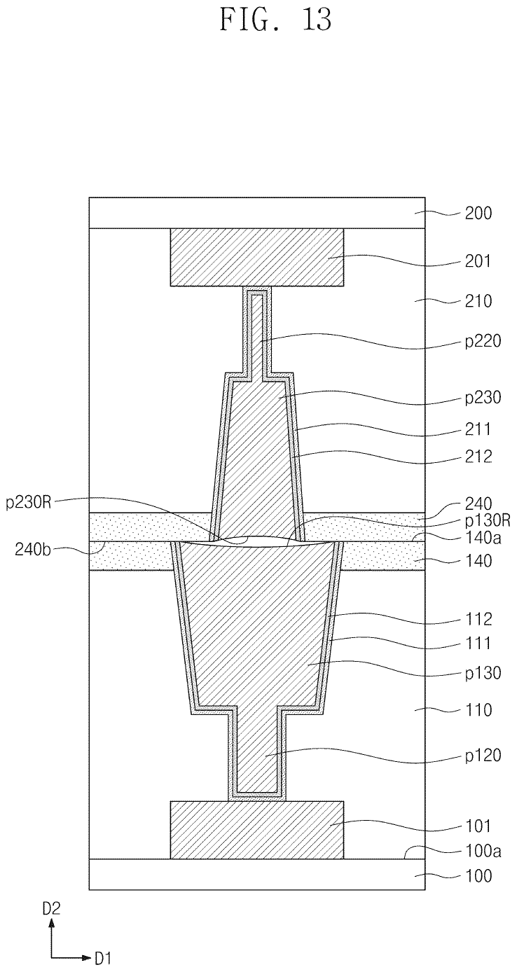

FIGS. 12 and 13 are sectional views illustrating a hybrid bonding process according to an example embodiment of the inventive concepts, which differs from that the example embodiment shown in FIGS. 8 and 9. In the following description, an element previously described with reference to FIGS. 8 and 9 may be identified by the same reference number without repeating an overlapping description thereof.

Referring to FIG. 12, the second protection seed pattern 212 may be additionally formed, compared with the example embodiment of FIG. 8. The second protection seed pattern 212 may be formed to conformally cover the second seed pattern 211. The second protection seed pattern 212 may include the same or substantially similar material as the first protection seed pattern 112 described with reference to FIG. 7 and may be formed through the same or substantially similar method as that for the first protection seed pattern 112.

Referring to FIG. 13, the top surface 140a of the first adhesive layer 140 and the bottom surface 240b of the second adhesive layer 240 may be attached to each other. Thus, the top surface 140a of the first adhesive layer 140 may be in contact with the bottom surface 240b of the second adhesive layer 240.

A void may be formed between the recessed top surface p130R of the preliminary first pad p130 and the recessed bottom surface p230R of the preliminary second pad p230.

Referring back to FIG. 2A, an annealing process may be performed on the resulting structure of FIG. 12. During the annealing process, a material included in the preliminary first and second pads p130 and p230, may be diffused to fill a void between the recessed top surface p130R of the preliminary first pad p130 and the recessed bottom surface p230R of the preliminary second pad p230. Thus, the first pad 130 may be in contact with the second pad 230, as shown in FIG. 2A.

In addition, a material included in the first and second protection seed patterns 112 and 212 may be diffused to form the first protection layer 150. In an example embodiment, manganese (Mn) included in the first and second protection seed patterns 112 and 212, may be diffused into a region between the first pad 130 and the second adhesive layer 240 and may react with oxygen, which is present in the region, to form the first protection layer 150.

According to an example embodiment of the inventive concepts, in a structure, which is formed by bonding a first semiconductor die to a second semiconductor die, a protection layer may be interposed between a pad and an adhesive layer. Thus, an adhesion strength between the first semiconductor die and the second semiconductor die may be increased.

In addition, by adjusting the mean grain size of the pad, it may be possible to block or prevent a material in the protection layer from being diffused into a bonding interface between the pads. Thus, a semiconductor device with improved electrical and/or reliability characteristics may be provided.

While some example embodiments of the inventive concepts have been particularly shown and described, it will be understood by one of ordinary skill in the art that variations in form and detail may be made therein without departing from the spirit and scope of the attached claims.

What is claimed is:

1. A semiconductor device, comprising:
a first semiconductor die including a first pad and a first adhesive layer, the first adhesive layer covering an upper portion of a side wall of the first pad;
a second semiconductor die including a second pad and a second adhesive layer, the second adhesive layer covering a lower portion of a side wall of the second pad; and
a first protection layer between the first pad and the second adhesive layer, wherein
a mean grain size of each of the first pad and the second pad ranges from 25 nm to 70 nm,
the second pad is on the first pad,
a top surface of the first pad includes an exposed top surface portion exposed by the second pad,
the second adhesive layer is on the exposed top surface portion of the first pad, and
the protection layer is between the exposed top surface portion of the first pad and the second adhesive layer.

2. The semiconductor device of claim 1, wherein the side wall of the first pad and the side wall of the second pad are spaced apart from each other in a first direction, the first direction being parallel to a top surface of the first adhesive layer.

3. The semiconductor device of claim 2, wherein
the side wall of the first pad is inclined at a first angle to the top surface of the first adhesive layer,
the side wall of the second pad is inclined at a second angle to the top surface of the first adhesive layer, and
the first angle and the second angle are obtuse angles.

4. The semiconductor device of claim 1, wherein
the first pad has a first width in a first direction, the first direction being parallel to a top surface of the first adhesive layer,
the second pad has a second width in the first direction, and
the first width and the second width decrease as a distance from the top surface of the first adhesive layer increases.

5. The semiconductor device of claim 1, wherein a center of the first pad and a center of the second pad overlap each other, when viewed in a plan view.

6. The semiconductor device of claim 1, wherein a center of the first pad and a center of the second pad are spaced apart from each other, when viewed in a plan view.

7. The semiconductor device of claim 1, further comprising:
a second protection layer between the second pad and the first adhesive layer,
wherein a bottom surface of the second pad includes an exposed bottom surface portion exposed by the first pad,
the exposed bottom surface portion of the second pad is on the first adhesive layer, and
the second protection layer is between the exposed bottom surface portion of the second pad and the first adhesive layer.

8. The semiconductor device of claim 1, wherein the first pad and the second pad partially overlap each other in a direction perpendicular to a top surface of the first adhesive layer.

9. The semiconductor device of claim 1, wherein
the first pad has a first width in a first direction, the first direction being parallel to a top surface of the first adhesive layer,
the second pad has a second width in the first direction, and
the first width and the second width are different from each other.

10. The semiconductor device of claim 9, wherein the first width is larger than the second width.

11. The semiconductor device of claim 1, wherein the first protection layer comprises manganese oxide.

12. A semiconductor device, comprising:
a first semiconductor die;
a second semiconductor die on the first semiconductor die; and
a first protection layer between the first semiconductor die and the second semiconductor die, wherein
the first semiconductor die comprises
a first substrate,
a first interconnection pattern on the first substrate,
a first via on the first interconnection pattern,
a first insulating layer on the substrate and covering the first interconnection pattern and the first via,
a first adhesive layer on the first insulating layer, and
a first pad penetrating the first adhesive layer and the first insulating layer and connected to the first via,
the second semiconductor die comprises
a second substrate,
a second interconnection pattern on the second substrate,
a second via on the second interconnection pattern,
a second insulating layer on the substrate and covering the second interconnection pattern and the second via,
a second adhesive layer on the second insulating layer, and
a second pad penetrating the second adhesive layer and the second insulating layer and connected to the second via,
a mean grain size of the first and second pads ranges from 25 nm to 70 nm,
the second pad is on the first pad,
a top surface of the first pad includes an exposed top surface portion exposed by the second pad,
the second adhesive layer is on the exposed top surface portion of the first pad, and
the first protection layer is between the exposed top surface portion of the first pad and the second adhesive layer.

13. The semiconductor device of claim 12, wherein a side wall of the first pad and a side wall of the second pad are spaced apart from each other in a first direction, the first direction being parallel to a top surface of the first substrate.

14. The semiconductor device of claim 12, wherein
the first pad has a first width in a first direction, the first direction being parallel to a top surface of the first substrate,
the second pad has a second width in the first direction,
the first width increases as a distance from the top surface of the first substrate in a vertical direction increases, the vertical direction being a direction perpendicular to the top surface of the first substrate, and
the second width decreases as a distance from the top surface of the first substrate in the vertical direction increases.

15. The semiconductor device of claim 14, wherein the first width of the uppermost portion of the first pad is larger than the second width of the lowermost portion of the second pad.

16. The semiconductor device of claim 12, wherein a center of the first pad and a center of the second pad overlap each other, when viewed in a plan view.

17. The semiconductor device of claim 12, wherein a center of the first pad and a center of the second pad are spaced apart from each other, when viewed in a plan view.

18. The semiconductor device of claim 12, further comprising:
a second protection layer between the first semiconductor die and the second semiconductor die,
wherein a bottom surface of the second pad includes an exposed bottom surface portion exposed by the first pad,
the exposed bottom surface portion of the second pad is on the first adhesive layer, and
the second protection layer is between the exposed bottom surface portion of the second pad and the first adhesive layer.

19. The semiconductor device of claim 18, wherein the first and second protection layers comprise manganese oxide.

20. The semiconductor device of claim 12, wherein a mean grain size of each of the first via and the second via ranges from 25 nm to 70 nm.
